(19) United States
(12) Patent Application Publication
(10) Pub. No.: US 2025/0183862 A1
(43) Pub. Date: Jun. 5, 2025

(54) DIFFERENTIAL AMPLIFIER WITH CONSTANT OPERATING CONDITIONS

(71) Applicant: Micron Technology, Inc., Boise, ID (US)

(72) Inventor: Jung-Hwa Choi, Boise, ID (US)

(21) Appl. No.: 18/939,242

(22) Filed: Nov. 6, 2024

Related U.S. Application Data
(60) Provisional application No. 63/605,925, filed on Dec. 4, 2023.

(51) Int. Cl. H03F 3/45; G11C 11/409

(52) U.S. Cl. CPC H03F 3/4521; H03F 3/45475; G11C 11/409; H03F 2200/255

(57) ABSTRACT

An electronic device including a differential amplifier that includes a ZQnodeCap terminal node and a RefnodeCap terminal node, and a peripheral circuit that is coupled to the differential amplifier, the peripheral circuit including a ZQnode terminal node and a Refnode terminal node configured to receive input signals to the electrical device, a CapZQ capacitor having a first terminal connected to the ZQnodeCap terminal node, a CapRef capacitor having a third terminal connected to the RefnodeCap terminal node and a fourth terminal connected to the Refnode terminal node of the peripheral circuit, a first precharging transistor connected to the ZQnodeCap terminal node; a second precharging transistor connected to the RefnodeCap terminal node; a third precharging transistor connected to a second terminal of the CapZQ capacitor at a ZQnodeInt node, and a fourth PassZQ transistor connected to the ZQnodeInt node.

### CROSS-REFERENCE TO RELATED APPLICATION(S)

The present application claims priority to U.S. Provisional Patent Application No. 63/605,925, filed Dec. 4, 2023, the disclosure of which is incorporated herein by reference in its entirety.

### TECHNICAL FIELD

The disclosed embodiments relate to electronic devices, and in particular, to differential amplifier devices having constant operating conditions for use with varying input signal levels.

### BACKGROUND

An impedance differential amplifier is a specialized type of differential amplifier that is designed to convert the impedance of an input signal (e.g., voltages) to a different impedance at the output. This type of amplifier is commonly used in memory devices and integrated circuits for signal conditioning and matching purposes. Standard differential amplifier device may include a current source, a differential pair of transistors, and load devices. The performance of the differential amplifier may be impacted by input signal levels, current supply from the current source, and others. The differential amplifier's capability to handle a wide range of input and output voltages without clipping or distortion is important for compatibility with various input signal levels. In particular, memory devices, such as dynamic random-access memory (DRAM), requires specific performance characteristics from differential amplifier circuits including a fast settling time and slew rate to ensure reliable data storage, retrieval, and communication. Differential amplifier devices should settle quickly to their final outputs when an input signal is changed. This is particularly important in high-speed memory interfaces to minimize the delay between signal transitions.

### BRIEF DESCRIPTION OF THE DRAWINGS

FIGS. 1A and 1B depict an example impedance comparator circuit.

FIG. 2 depicts a differential amplifier adopted in the example impedance comparator circuit of FIG. 1.

FIG. 3 depicts a differential amplifier coupled with a peripheral circuit in accordance with an embodiment of the present technology.

FIG. 4 depicts a voltage generator circuit in accordance with an embodiment of the present technology.

FIGS. 5A, 5B, and 5C depict an impedance comparator circuit in accordance with an embodiment of the present technology.

FIG. 6 depicts simulation waveforms of the differential amplifier device of FIG. 3 during various operation phases in accordance with an embodiment of the present technology.

FIGS. 7 and 8 depict simulation waveforms of the impedance comparator circuit of FIG. 5 during compare phase in accordance with an embodiment of the present technology.

FIG. 9 is a flow diagram illustrating an example method of operating the differential amplifier in accordance with an embodiment of the present technology.

FIG. 10 is a schematic view of a system that includes a memory device in accordance with an embodiment of the present technology.

The drawings illustrate only example embodiments and are therefore not to be considered limiting in scope. The elements and features shown in the drawings are not necessarily to scale, emphasis instead being placed upon clearly illustrating the principles of the example embodiments. Additionally, certain dimensions or placements may be exaggerated to help visually convey such principles. In the drawings, the same reference numerals used in different embodiments designate like or corresponding, but not necessarily identical, elements.

### DETAILED DESCRIPTION

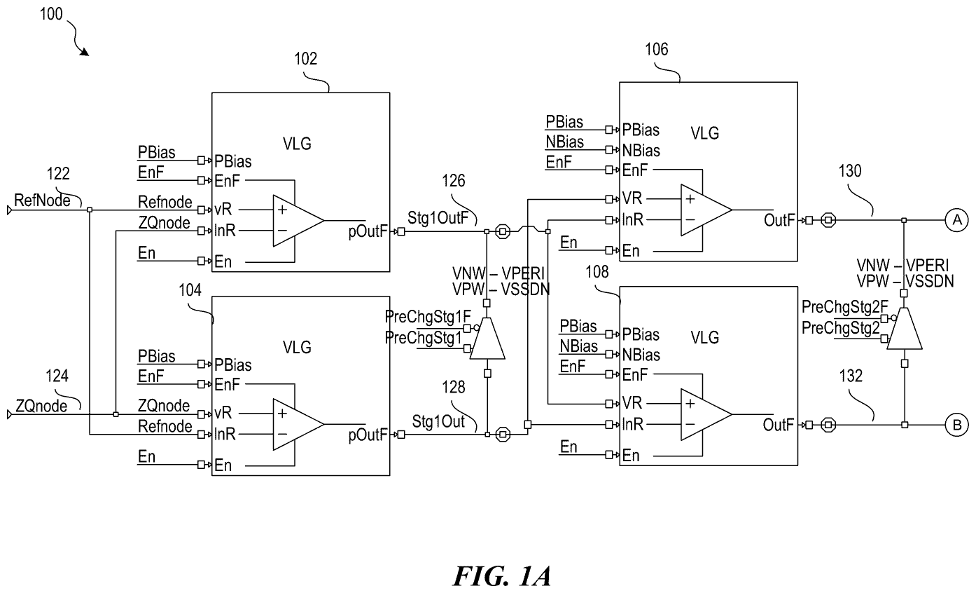

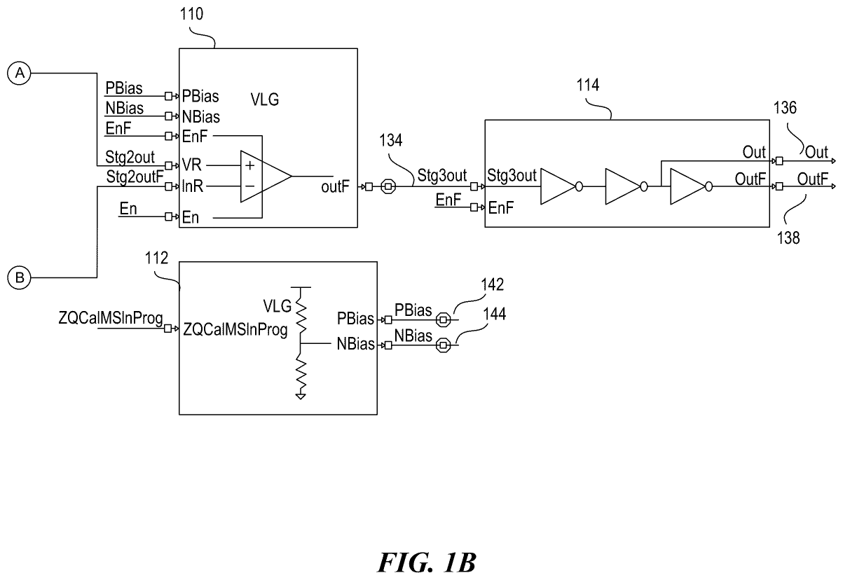

Impedance comparator circuits are essential components of semiconductor devices such as DRAM memory for various applications. For example, a data queue (ZQ) impedance comparator circuit can be used to measure and compare the impedance of selected memory cells with a reference impedance. This reference impedance might be generated internally or provided externally, depending on the memory device design. FIGS. 1A and 1B depict an example ZQ comparator circuit 100, which include three stages of paired differential amplifiers to achieve a high cumulative gain. For example, as shown in FIG. 1A, the ZQ comparator circuit 100 can include differential amplifiers 102 and 104 that can be arranged in parallel at the first stage. In addition, the ZQ comparator circuit 100 includes differential amplifiers 106 and 108 that are connected in parallel. The output nodes 126 and 128 of the differential amplifiers 102 and differential amplifiers 104 are both connected to input terminals of the second stage differential amplifiers 106 and 108. In this example, the configuration of the differential amplifiers 106 and 108 can be identical to the differential amplifiers 102 and 104 at the first stage. Further, the differential amplifiers 106 can have an output node 130 and the differential amplifiers 108 can have an output node 132. As shown in FIG. 1B, the differential amplifier 110 has two input terminals that are connected to the output nodes 130 and 132 of the second stage of differential amplifiers 106 and 108. The comparison signal can be further processed in the output circuit 114 and transferred out of the ZQ comparator circuit 100 through final output terminals 136 and 138. Here, the voltage generator 112 can be configured to provide reference voltages to the differential amplifiers included in the ZQ comparator circuit 100. In this example, the voltage input can be input voltage difference of the differential pair. Specifically, the voltage difference between the ZQnode and Refnode along with PMOS diff pair of each of the differential amplifiers can cause the current steering. The NMOS active load device coupled to the differential pair can convert the steered currents into the voltage output. The output gain of each differential amplifier device is a proportional to the bias current and the active load resistance. In this example, the Vout of each stage of ZQ comparator circuit 100 can be the output voltage difference of corresponding stage pair (e.g., Stg1Out−Stg1OutF). Therefore, a gain for each stage of ZQ comparator can be Vout/Vin=(Stg1Out−Stg1OutF)/(ZQnode−Refnode).

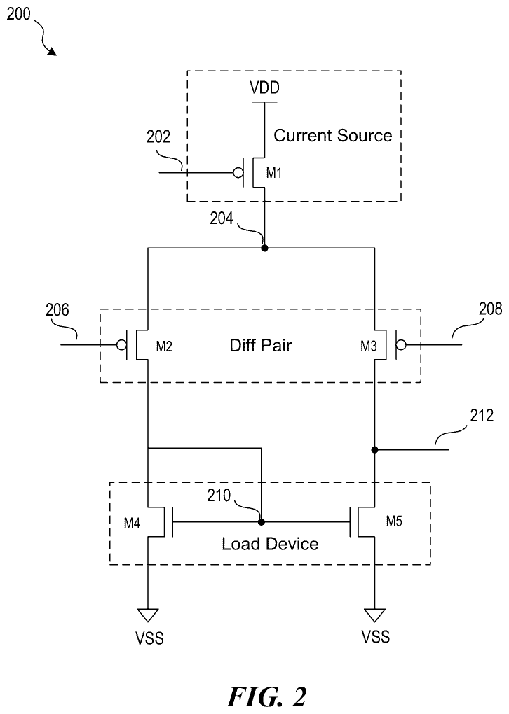

FIG. 2 illustrates an example circuit diagram of a differential amplifier 200 that can be implemented to the ZQ comparator circuit 100 describe above. In particular, the differential amplifier 200 including transistor devices at one or more portions therein can be implemented for a memory device (e.g., a DRAM device). For example, the differential amplifier 200 can be included in one or more data terminal (DQ) connections (e.g., within input buffers) that are configured to receive a data (DQ) signal to be written into a memory location.

The differential amplifier 200 can include one or more transistors (e.g., N-channel transistors and/or P-channel transistors) configured to receive and process corresponding input signals such as a write enable signal, a DQ system signal (e.g., DQSB, DQST, etc.), the data (DQ) signal, a DQ external voltage signal, or a combination thereof. In some embodiments, the DQ system signal can include the DQSB signal corresponding to a bar signal of a data strobe signal (DQS), the DQST corresponding to a true signal of DQS, or a combination thereof. Accordingly, the differential amplifier 200 can generate an output signal based on receiving and processing the input signals.

In some embodiments, the differential amplifier 200 can include a P-channel transistor (M1) to connect a supply voltage (VDD; e.g., connected to a source of M1) to the other transistors. For example, M1 can be OFF when the PBias terminal 202 signal is at an inactive high level, when no data signal to be written is supplied to the differential amplifier 200, thereby reducing a leakage current. A drain of M1 can be connected to sources of one or more further P-channel transistors (M2 and/or M3) operated by the DQ signal connected to gates thereof. In one or more embodiments, M2 and/or M3 can be a differential amplifier or a portion thereof such that the gate of M2 is connected to a positive connection of the DQ signal and M3 is connected to a negative connection of the DQ signal (e.g., a reference node (Vref)). Drains of M2 and/or M3 can be connected to VSS ground through corresponding loading devices (e.g., N-channel transistors M4 and M5, respectively). In some other embodiments, the differential amplifier 200 may include a number of precharging transistors that can be operated according to a data strobe signal (DQS) or derivatives thereof (e.g., the DQST and/or the DQSB signals) to precharge the respective nodes.

In some embodiments, the drains of M2 and/or M3 can further be connected to drains of corresponding N-channel transistors (M4 and M5, respectively) for further amplifying an output of the differential amplifier (e.g., M2 and M3). Sources of the amplifying transistors (M4 and/or M5) can be connected to the VSS ground and gates of the amplifying transistors (M4 and/or M5) can be connected to a common connection node 210. In this example, the drains of the upstream output transistors can generate the output signal. For example, the drain of M3 (and/or M2) can generate a differential high portion of the output signal (OUT+). In some other examples, the drain of M3 (and/or M2) can generate a differential negative portion of the output signal (OUT−). One or more of the upstream output transistors (e.g., M1 and/or M2) can be operated according to the opposing differential output connected to the gates thereof. For example, the gate of M2 can be connected to ZQnode (ZQ pad) output voltage and/or the gate of M3 can be connected to the Refnode output voltage. In some embodiments, the differential amplifier 200 can be used to connected with output nodes, such as OUT+ and/or OUT− nodes, wherein they can be further connected to one or more downstream differential amplifier devices for multiple stages signal amplification.

There are limitations when implementing the differential amplifier 200 with a ZQ pad to monitor the ZQ pad voltage levels. In particular, the performance of the differential amplifier 200 is hard to control when the input voltage signal (e.g., the ZQnode node 206 voltage) fluctuates during the operations. The differential amplifier 200 may only provide demanded performance when the input ZQnode and Refnode signals are within a certain range. For example, in advanced memory devices such as LP4 and LP5 families of DRAM devices, the customers are allowed to apply a variable VDDQ voltages to vary the DRAM clock frequency in order to optimize the memory device I/O performance or power consumption. During a general high-speed DRAM device operation, the VDDQ voltage can be configured to be around 0.5V. One example mode of operating LP5 family DRAM device is dynamic voltage and frequency scaling VDDQ (DVFSQ). In this mode, the system configuration may reduce the VDDQ level to better control the LPDRAM device energy consumption. In another example, even though a current JEDEC specification only uses a single calibration voltage (e.g., VOH=VDDQ*0.5) during the ZQ calibration, it is further possible to expand the VOH calibration voltage range in an updated JEDEC specification. Specifically, it is possible to adjust the VOH voltage to a wider operation range (e.g., from VOH=VDDQ*0.25 to VOH=VDDQ*0.75).

When the VOH and VDD voltage levels change, the operation condition of the differential amplifier changes. For example, when the VOH is configured to be 0.25V (e.g., VDDQ*0.5) and the VDD is configured to be 0.96V, the source-drain voltage of current source transistor (e.g., M1 of differential amplifier 200 descripted in FIG. 2) can be around 0.2V, causing the M1 transistor working at a saturation region and providing enough source current to the differential pair of transistors M2 and M3 for amplification. In contrast, when the VOH is configured to be 0.45V (e.g., VDDQ*0.75) and the VDD is constant as 0.96V, the source-drain voltage of current source transistor (e.g., M1 of differential amplifier 200 descripted in FIG. 2) can be around 0.01V, causing the M1 transistor working at a linear region and providing limited source current to underneath differential pair of transistors M2 and M3 for amplification. In the latter example described above, it can be found that at high VOH and low VDD, the voltage headroom of the differential amplifier becomes smaller. With that, the current source (e.g., transistor M1) coupled to the differential amplifier 200 goes into the linear region, causing a reduced source current and slowing down the ZQ comparator circuit 100.

The present technology discloses peripheral circuit components that can be included in a ZQ comparator circuit and/or coupled to differential amplifier devices. The peripheral circuit components include various numbers of precharging transistors and capacitors that used to configure the input voltages to the pair of differential transistors of the differential amplifier devices at a constant and relative low voltage level. This constant and relatively low voltage level (e.g., constantly at 0.18V, or at a certain voltage level ranging from 100 mV to 250 mV) configuration of the input voltages helps maintaining a large enough room for the current source transistor coupled to the differential amplifier device to work at a saturation mode, therefore delivering enough current through the underneath differential pair transistors for signal comparison.

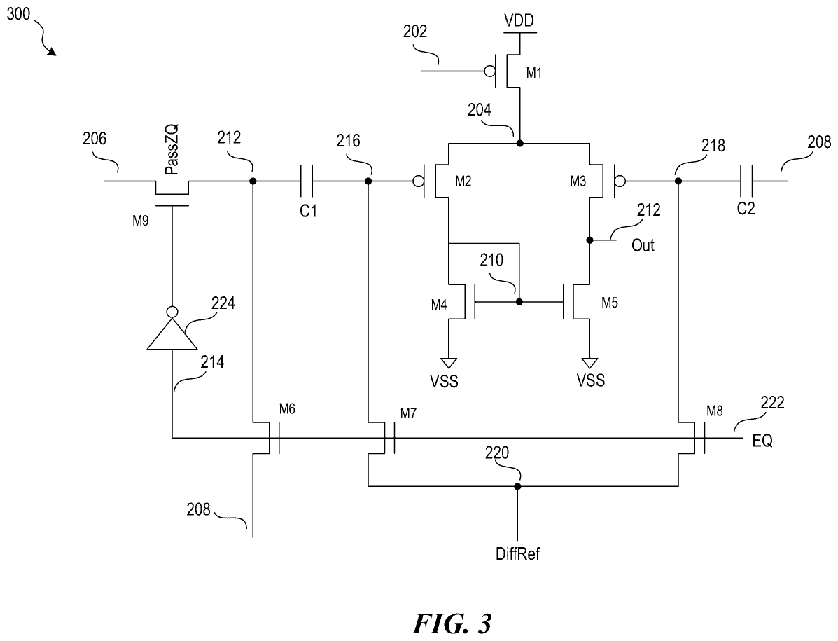

FIG. 3 illustrates a differential amplifier 300 with peripheral circuit components in accordance with an embodiment of the present technology. The differential amplifier 300 also includes a current source, a differential pair of transistors, and loading devices that are similar to the ones described in FIG. 2. For example, the differential amplifier 300 can include a P-channel transistor (M1) to connect a supply voltage VDD to the other transistors. M1 can be OFF when the PBias terminal 202 signal is at an inactive high level, when no data signal to be written is supplied to the differential amplifier 200, thereby reducing a leakage current. In this example, the drain of M1 transistor can be connected to sources of one or more further P-channel transistors (M2 and/or M3) operated by the ZQnodeCap and RefnodeCap signals connected to gates thereof. In one or more embodiments, the M2 and/or M3 transistors can be a differential amplifier or a portion thereof. The drains of M2 and/or M3 transistors can be connected to VSS ground through corresponding loading devices (e.g., N-channel transistors M4 and M5, respectively).

In this example, The M2 and M3 transistors can be arranged in parallel, having their source terminals connected to the drain of the M1 transistor at a common connection node 204. The drains of M2 and/or M3 transistors can further be connected to drains of corresponding N-channel transistors (M4 and M5, respectively) for further amplifying an output of the differential amplifier (e.g., M2 and M3). Sources of the amplifying transistors (M4 and/or M5) can be connected to the VSS ground and gates of the amplifying transistors (M4 and/or M5) can be connected to a common connection node 210. Here, the drains of the upstream output transistors can generate the output signal at the ZQnodeCap and RefnodeCap nodes, respectively. For example, the drain of M3 (and/or M2) transistor can generate a differential high portion of the output signal (OUT+). In some other examples, the drain of M3 (and/or M2) transistor can generate a differential negative portion of the output signal (OUT−). One or more of the upstream output transistors (e.g., M2 and/or M3) can be operated according to the opposing differential output connected to the gates thereof.

As shown in FIG. 3, the differential amplifier 300 may also include peripheral circuit components such as capacitors, transistors, and inverters to provide constant input voltages to the pair of differential transistors (e.g., M2 and M3). For example, the differential amplifier 200 may also include a number of precharging transistors that can be operated according to an EQ signal or derivatives thereof (e.g., the DQST and/or the DQSB signals) to precharge the respective nodes. In addition, the differential amplifier 200 may also include a number of capacitors coupled to the differential pair of M2 and M3 transistors. For example, a first terminal of a CapZQ C1 capacitor can be connected to the gate terminal of the M2 transistor at the ZQnodeCap terminal node. In contrast, another CapRef C2 capacitor can have its one terminal connected to the gate terminal of the M3 transistor at the RefnodeCap node. Further, the differential amplifier 200 may also include precharging transistors M6, M7, and M8 that are connected on the EQ signal line 222 in series. In this example, the precharging transistor M7 has a drain terminal connected to the ZQnodeCap terminal node 216, the precharging transistor M8 has a drain terminal connected to the RefnodeCap terminal node 218. Here, the drain terminal of the precharging transistor M7 and the drain terminal of the precharging transistor M8 are connected to a DiffRef node 220. In addition, the precharging transistors M7 and M8 are arranged in parallel with respect to the differential pair of M2 and M3 transistors. Further, the differential amplifier 200 includes a precharging transistor M6 having a drain terminal connected to a second terminal of the CapZQ C1 capacitor at the ZQnodeInt node 212, wherein gate terminals of the precharging transistors M6, M7, and M8 are all connected in series on the EQ signal line. Moreover, the differential amplifier 200 may also include a PassZQ M9 transistor having a source terminal connected to the ZQnodeInt node 212, a drain terminal connected to the ZQnode terminal node 206, and a gate terminal connected to the EQ signal line 222 through an inverter 224.

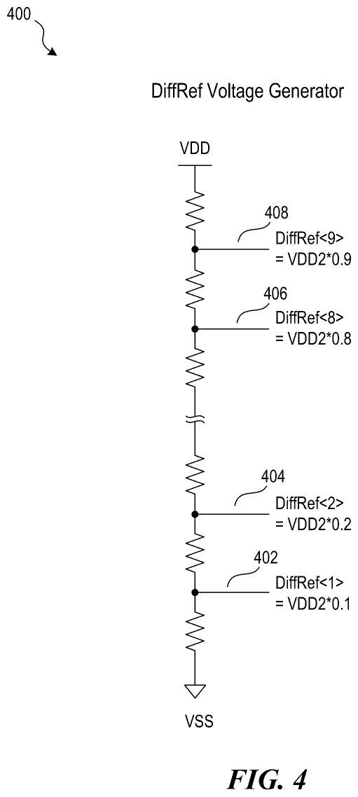

A DiffRef voltage can be provided to the source terminals of the loading transistors M7 and M8 and DiffRef node 220, and generated from a voltage generator 400 included in the ZQ comparator circuit. As shown in FIG. 4, the voltage generator 400 can include a plurality of resistors that are connected in series. One end of the plurality of resistors connected in series can be connected to the VDD source, and another end of the plurality of resistors can be connected to the VSS ground. As illustrated in FIG. 4, each one of the resistors may have a same resistance, e.g., ranging from 10 ohms to 10 Kohms. The DiffRef voltage generator outputs a DiffRef voltage to the DiffRef node 220 of the differential amplifier 300 by partitioning voltage applied on the plurality of resistors. Accordingly, the DiffRef voltage can be a portion of the VDD, e.g., VDD*0.1 at output node 402, VDD*0.2 at output node 404, VDD*0.8 at output node 406, or VDD*0.9 at output node 408.

The differential amplifier 300, combined with voltage generator 400, can be configured to provide constant operation conditions to its pair of differential transistors (e.g., M2 and M3) for input signal comparison. Before the comparison of input signals starts, the capacitor voltages can be initialized with the precharge transistors and the internal reference voltage DiffRef, before the ZQnode (ZQ pad) voltage is being applied for the comparator. For example, at a beginning period of the initialization stage, the EQ signal can be adjusted in a high level to turn on the precharging transistors M6, M7, and M8. The DiffRef voltage can be configured to the ZQnodeCap node 216 and the RefnodeCap node 218. In addition, the Refnode voltage can be configured to the ZQnodeInt node 212 and the external terminal of the CapRef C2 capacitor. In general, the voltage generator 400 can be configured to provide the DiffRef voltage ranging from 0 to 100% of the VDD, in order to target a proper input voltage for a best performance of the differential amplifier 300. In this example, the DiffRef voltage can be set to be 0.18V. When the EQ signal is configured to be high, the ZQnodeCap node 216 and refnodeCap node 218 are precharged as 0.18V too. Here, the Refnode can be charged to 0.3V. So when the EQ signal is high, the ZQnodeInt node 212 has a voltage of 0.3V and forms a 0.12V voltage difference on the CapZQ C1 capacitor as well as the CapRef C2 capacitor. In this initialization stage, the voltage level for ZQnode node 206 and Refnode node 208 can both be around 0.3V.

After initializing the capacitors, the PassZQ M9 transistor connects the ZQnode pad and one end of the CapZQ C1 capacitor. During the following compare cycle, the ZQnode voltage will move the input voltage of the differential amplifier 300 using the CapZQ C1 capacitor, allowing the ZQ comparator circuit to compare the ZQ pad voltage to the ZQ reference voltage with constant voltage conditions applied to the first pair of differential transistors (e.g., M2 and M3). Specifically, in the compare cycle, the EQ signal will be turned to a lower level, turning off the precharging transistors M6, M7, and M8. Being disconnected from voltage sources, the ZQnodeInt node, the ZQnodeCap note, and the RefnodeCap will be floating. Meanwhile, the PassZQ M9 transistor is turned on through applying a low EQ signal to the inverter 224 which is connected to the gate terminal thereof.

During the operation, there might be a ZQ pad external voltage fluctuation (e.g., from 0.3V to 0.31V). The ZQnode voltage variance can be then transferred to the ZQnodeCap node 216, through the PassZQ M9 transistor and the CapZQ C1 capacitor. In this example, the 0.01V ZQnode voltage variation will be transferred to the ZQnodeCap node 216, changing its voltage from 0.18V to 0.19V. At this point, the RefnodeCap node 218 has a constant voltage at 0.18V because there is no voltage change at the Refnode node 208 and the corresponding precharging transistor M8 is turned off. Comparing the input voltage levels at the ZQnodeCap node 216 (e.g., 0.19V) and the RefnodeCap node 218 (e.g., 0.18V), there is a 0.01V input voltage variance being forwarded to the differential amplifier 300 for comparison.

It can be further found that the voltage levels of the ZQnodecap node and RefnodeCap node can be halted at a constant level, e.g., a relative low voltage level comparing to the ZQnode node 206 and Refnode node 208, therefore leaving enough room for the current source coupled to the pair of differential transistors. This can help maintain the current source (e.g., the M1 transistor) working at a proper region such as a saturation region so that the current source can flow enough current through the underneath differential pair transistors for comparison. This configuration of differential amplifier 300 can be used to main a stable or achieve a better ZQ comparator circuit performance when the ZQ node inputs varies.

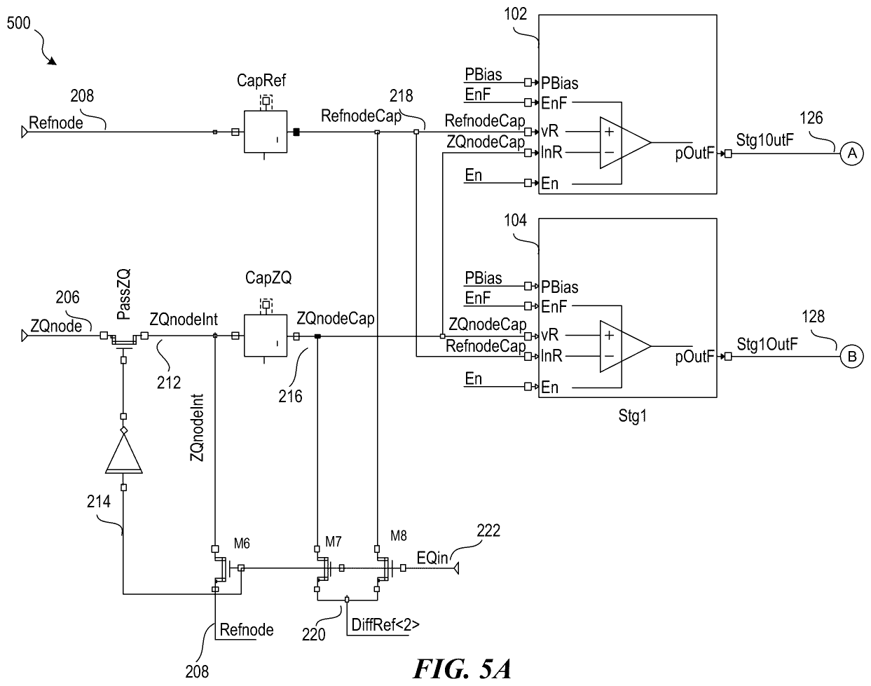

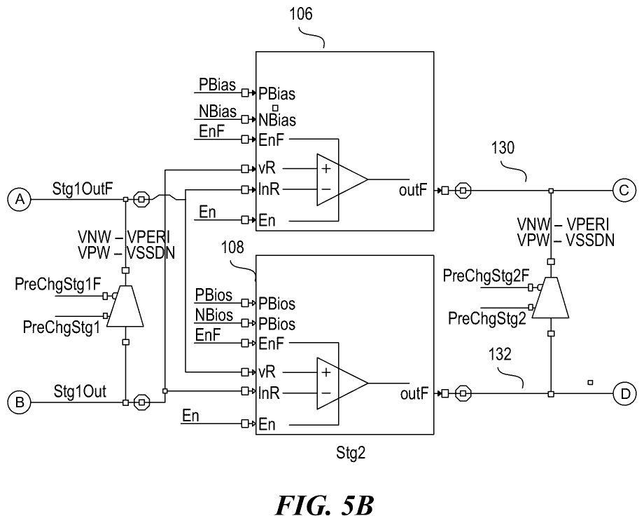

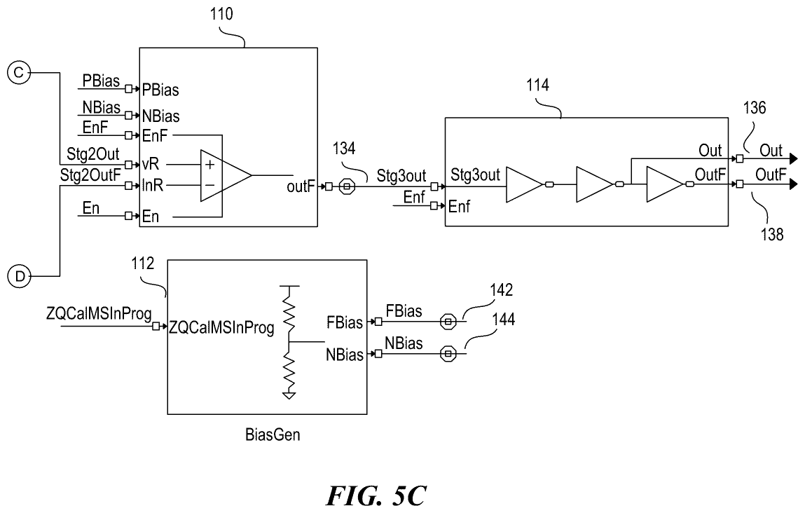

The peripheral circuit component included in the differential amplifier 300 can be adopted in a multiple stage ZQ comparator for circuit performance improvement. For example, FIGS. 5A, 5B, and 5C illustrate a ZQ comparator circuit 500 in accordance with an embodiment of the present technology. The ZQ comparator circuit 500 can include multiple stages of paired differential amplifiers to achieve a high cumulative gain. For example, the ZQ comparator circuit 500 can include three stages of paired differential amplifiers for a total cumulative gain ranging from 730 to 920. In this example, as shown in FIG. 5A, the differential amplifiers 102 and 104 can be arranged in parallel at the first stage of paired differential amplifiers. In particular, peripheral circuit component included in the differential amplifier 300 can be included in the ZQ comparator circuit 500. In this example, the RefnodeCap node 218 can be connected to a RefnodeCap input ports of the differential amplifiers 102 and 104. Further, the ZQnodeCap node 216 can also be connected to the ZQnodeCap input ports of the differential amplifiers 102 and 104. Other interconnections of peripheral circuit component can be similar as described in FIG. 3. As shown in FIG. 5A, the differential amplifiers 102 can have an output node 126 and the differential amplifiers 104 can have an output node 128.

Turning to a second stage of the ZQ comparator circuit 500 which includes differential amplifiers 106 and 108 that are connected in parallel and shown in FIG. 5B. The output nodes 126 and 128 of the differential amplifiers 102 and differential amplifiers 104 are both connected to input terminals of the second stage differential amplifiers 106 and 108. In this example, the configuration of the differential amplifiers 106 and 108 can be identical to the differential amplifiers 102 and 104 at the first stage. As shown in FIG. 5B, the differential amplifiers 106 can have an output node 130 and the differential amplifiers 108 can have an output node 132.

Further turning to a third stage of the ZQ comparator circuit 500 which includes a differential amplifier 110, as shown in FIG. 5C. The differential amplifier 110 has two input terminals that are connected to the output nodes 130 and 132 of the second stage differential amplifiers 106 and 108. The comparison signal can be further processed in the output circuit 114 and transferred out of the ZQ comparator circuit 500 through final output terminals 136 and 138. Here, the ZQ comparator circuit 500 also includes a bias generator 112 which uses a diode connected NMOS (e.g., gate and drain tied together) in series with a set of resistors to create NBIAS. When the NBIAS signal is connected to the gate of another NMOS (such as in differential amplifier 106 or 110), a current mirror is formed between the diode connected NMOS in bias generator 112 and the NMOS in a differential amplifier 106 or 110. The bias generator 112 uses a diode connected PMOS (e.g., gate and drain tied together) in series with a set of resistors to create PBIAS. When the PBIAS signal is connected to the gate of another PMOS (such as in differential amplifier 102, 106 or 110), a current mirror is formed between the diode connected PMOS in bias generator 112 and the PMOS in differential amplifier 106 or 110. In the present technology, the voltage generator 400 described in FIG. 4, as a resistor divider, can be also placed in the ZQ comparator circuit 500.

In some other embodiments, the ZQ comparator circuit 500 may include a number of stages of paired differential amplifiers (e.g., four stages, five stages), having the peripheral circuit component included in the differential amplifier 300 coupled to a first stage paired differential amplifiers thereof.

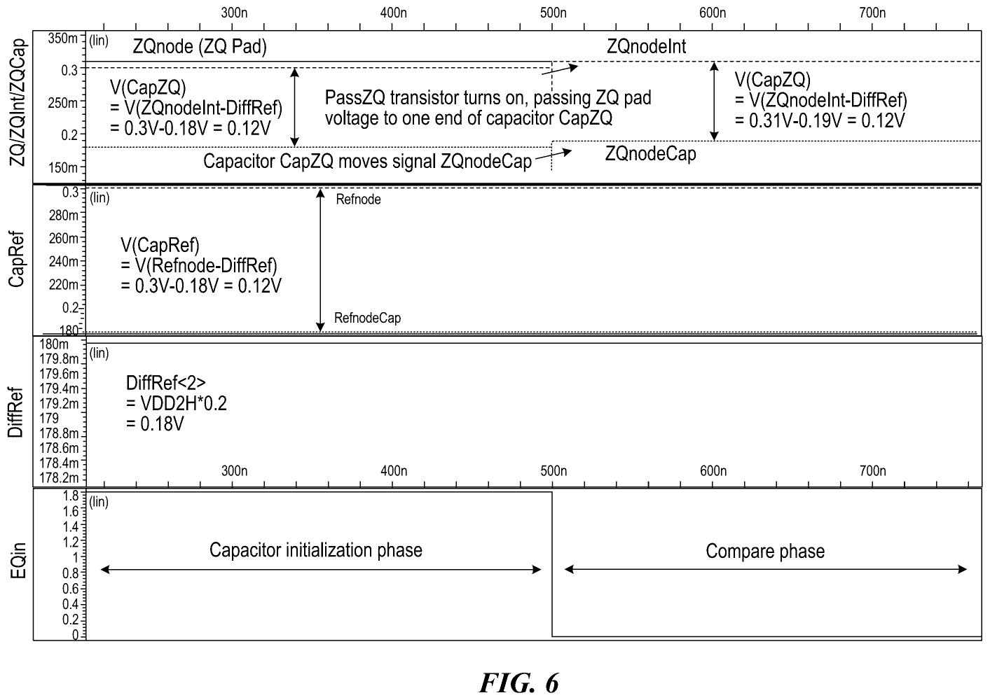

FIG. 6 shows simulation waveforms of the differential amplifier 300 during the capacitor initialization phase and compare phase of the operation in accordance with an embodiment of the present technology. As shown, the capacitor initialization phase lasts from beginning to 500 ns. During this initialization stage, the ZQnode node 206 and Refnode node 208 are both set to be at 0.3V. The EQ signal is turned high therefore the precharging transistors M6, M7, and M8 are all turned on. In this situation, the DiffRef voltage (e.g., DiffRef voltage output from output node 404 of the voltage generator 400) can be configured to be at Vdd*0.2=0.18V. The DiffRef voltage can be transferred to the ZQnodeCap node 216 as well as the RefnodeCap node 218.

At 500 ns, the operation of the differential amplifier 300 moves to the compare stage. In particular, the EQ signal can be configured to be low, turning off the pre-charging transistors M6, M7, and M8 and leaving ZQnodeInt node 212, ZQnodeCap node 216, and RefnodeCap node 218 all in a floating mode. Moreover, the low EQ signal can turn on the PassZQ transistor M9 through the inverter 224, through which the ZQnode voltage can be transferred to the ZQnodeInt node 212. As shown in FIG. 6, a ZQ pad voltage fluctuation may be introduced to the comparison. For example, the ZQnode 206 voltage can be raised from 0.3V to 0.31V. In this stage, the ZQnode input voltage variance can be transferred to the ZQnodeCap node 216, raising its voltage level from 0.18V to 0.19V. Here, the voltage delta crossing the CapZQ C1 is constant as 0.12V. In this stage, the RefnodeCap node 218 voltage is also constant, being close to the DiffRef voltage (Vdd*0.2=0.18V). Till now, the input voltages at the ZQnodeCap node 216 and the RefnodeCap node 218 of the differential pair of transistors (M2 and M3) are 0.19V and 0.18V. Since the voltages at the ZQnodeCap node 216 is constant and relatively low, the current source can maintain working at a saturation mode to passing current flow the differential amplifier 300 for comparison operation.

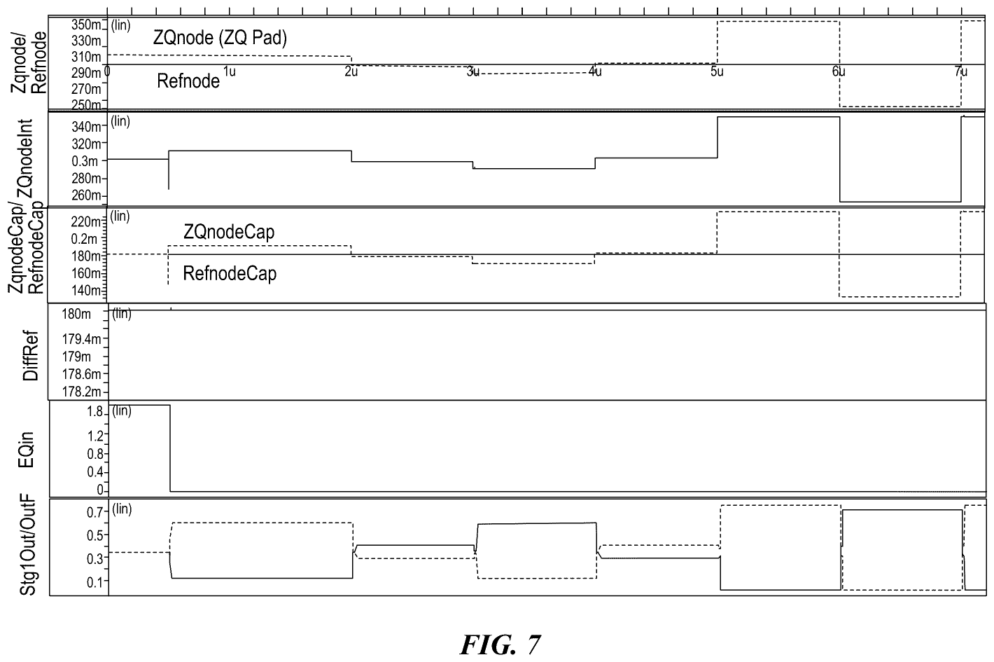

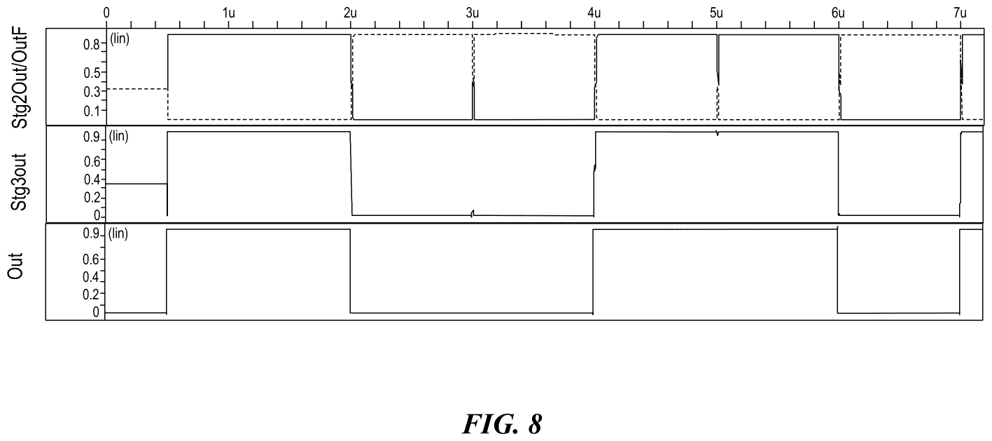

FIGS. 7 and 8 depict simulation waveforms of ZQ comparator circuit 500 of FIG. 5 during the compare phase in accordance with an embodiment of the present technology. As shown, a first compare phase lasts from beginning to 2 us. During this period, the ZQnode voltage level is set to be 0.31V and the Refnode voltage is constant at 0.3V. After the comparison, the outputs of first stage of the differential amplifiers 102 and 104 can be around 0.1V and 0.6V, respectively. The second stage paired differential amplifiers 106 and 108 can compared the incoming stage 1 output signals Stg1Out/OutF and provide output voltages at 0.05V and 0.85V, respectively. After the second stage output signals Stg2Out/OutF being processed by the differential amplifier 110, the Stg3out output signal thereof can be close to 1.0V.

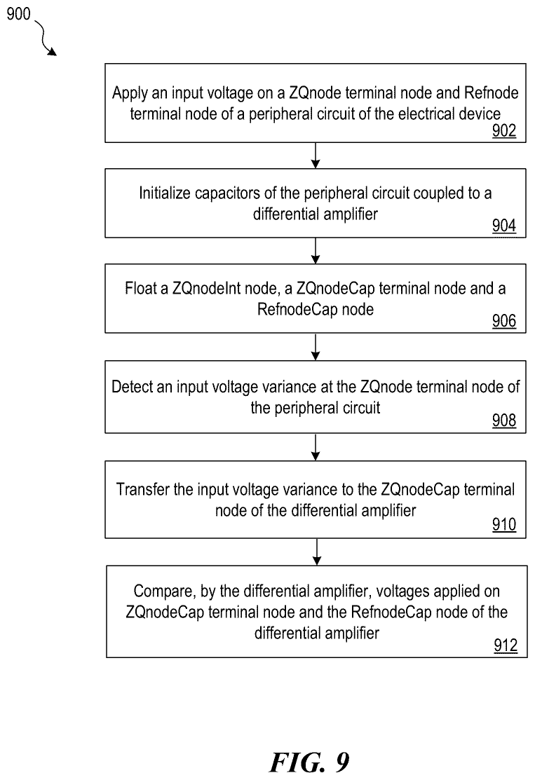

FIG. 9 is a flow diagram illustrating an example method 900 of operating the differential amplifier 300 in accordance with an embodiment of the present technology. For example, the method 900 can include applying an input voltage on a ZQnode terminal node and Refnode terminal node of a peripheral circuit of the electrical device, at 902. For example,

The method 900 may also include initializing capacitors of the peripheral circuit coupled to a differential amplifier, at 904. For example, during the initialization phase, the CapZQ C1 capacitor and CapRef C2 capacitors can both be initialized through applying Refnode voltage and DiffRef voltages at the two terminals thereof.

In addition, the method 900 may include floating a ZQnodeInt node, a ZQnodeCap terminal node and a RefnodeCap node, wherein the peripheral circuit is connected to the differential amplifier at the ZQnodeCap terminal node and the RefnodeCap node, at 906. For example, the EQ signal can be set to be low, therefore turning off the precharging transistors M6, M7, and M8. Accordingly, the ZQnodeInt node 212, the ZQnodeCap terminal node 216 and the RefnodeCap node 218 will be converted to a floating mode.

Further, the method 900 may include detecting an input voltage variance at the ZQnode terminal node of the peripheral circuit at 908. For example, there can be ZQ pad voltage variance incoming to the differential amplifier 300 for comparison. As described in FIG. 3, the ZQnode voltage may raise from 0.3V to 0.31V.

The method 900 may also include transferring the input voltage variance to the ZQnodeCap terminal node of the differential amplifier, at 910. For example, the 0.1V voltage variance from the ZQnode terminal 206 can be transferred to the ZQnodeCap node 216, through the PassZQ M9 transistor and CapZQ C1 capacitor. The transfer of the ZQnode voltage variance needs low EQ signal in order to turn on the PassZQ M9 transistor.

Lastly, the method 900 may include comparing, by the differential amplifier, voltages applied on ZQnodeCap terminal node and the RefnodeCap node of the differential amplifier, at 912. For example, after the voltage variance transferred to the ZQnodeCap node 216, the voltage inputs to the pair of differential amplifier transistor (e.g., M2 and M3) are 0.19V and 0.18V. The relatively low and constant ZQnodeCap node 216 voltage ensures the current source M1 transistor working at saturation mode, which in turn assist the input signals comparison in the differential amplifier 300.

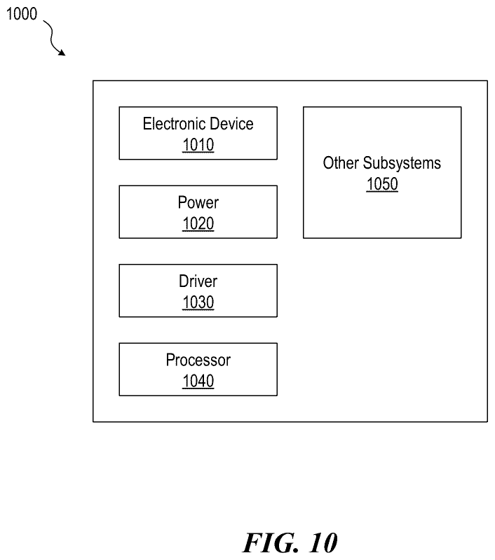

Any one of the semiconductor structures described above with reference to FIGS. 3-9 can be incorporated into any of a myriad of larger and/or more complex systems, a representative example of which is system 1000 shown schematically in FIG. 10. The system 1000 can include an electronic device 1010, a power source 1020, a driver 1030, a processor 1040, and/or other subsystems or components 1050. The electronic device 1010 can include features generally similar to those of the differential amplifier devices and/or ZQ comparator circuits described above and can therefore include the peripheral circuit components described in the present technology. The resulting system 1000 can perform any of a wide variety of functions, such as memory storage, data processing, and/or other suitable functions. Accordingly, representative systems 1000 can include, without limitation, hand-held devices (e.g., mobile phones, tablets, digital readers, and digital audio players), computers, and appliances. Components of the system 1000 may be housed in a single unit or distributed over multiple, interconnected units (e.g., through a communications network). The components of the system 1000 can also include remote devices and any of a wide variety of computer-readable media.

Specific details of several embodiments of semiconductor devices, and associated systems and methods, are described below. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

In accordance with one aspect of the present disclosure, the semiconductor devices illustrated above could be memory dice, such as dynamic random access memory (DRAM) dice, NOT-AND (NAND) memory dice, NOT-OR (NOR) memory dice, magnetic random access memory (MRAM) dice, phase change memory (PCM) dice, ferroelectric random access memory (FeRAM) dice, static random access memory (SRAM) dice, or the like. In an embodiment in which multiple dice are provided in a single assembly, the semiconductor devices could be memory dice of a same kind (e.g., both NAND, both DRAM, etc.) or memory dice of different kinds (e.g., one DRAM and one NAND, etc.). In accordance with another aspect of the present disclosure, the semiconductor dice of the assemblies illustrated and described above could be logic dice (e.g., controller dice, processor dice, etc.), or a mix of logic and memory dice (e.g., a memory controller die and a memory die controlled thereby).

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “top,” “bottom,” “over,” “under,” “above,” and “below” can refer to relative directions or positions of features in the semiconductor devices in view of the orientation shown in the Figures. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. An electrical device, comprising:
a differential amplifier including a ZQnodeCap terminal node and a RefnodeCap terminal node; and
a peripheral circuit coupled to the differential amplifier, the peripheral circuit including:
a ZQnode terminal node and a Refnode terminal node configured to receive input signals to the electrical device,
a CapZQ capacitor having a first terminal connected to the ZQnodeCap terminal node,
a CapRef capacitor having a third terminal connected to the RefnodeCap terminal node and a fourth terminal connected to the Refnode terminal node of the peripheral circuit,
a first precharging transistor having a first source terminal connected to the ZQnodeCap terminal node,
a second precharging transistor having a second source terminal connected to the RefnodeCap terminal node; wherein a first drain terminal of the first precharging transistor and a second drain terminal of the second precharging transistor are connected to a DiffRef node, and the first and second precharging transistors are arranged in parallel with respect to the differential amplifier,
a third precharging transistor having a third source terminal connected to a second terminal of the CapZQ capacitor at a ZQnodeInt node, wherein gate of the first, second, and third precharging transistors are connected in series on an EQ signal line, and
a fourth PassZQ transistor having a fourth source terminal connected to the ZQnodeInt node, a fourth drain terminal connected to the ZQnode terminal node, and a fourth gate terminal connected to the EQ signal line through an inverter.

2. The electrical device of claim 1, wherein the differential amplifier includes:
a current source including a PMOS transistor, wherein a fifth source terminal of the PMOS transistor is connected to a VDD source and a fifth gate terminal of the PMOS transistor is connected to a bias source,
a differential pair of PMOS transistors arranged in parallel, wherein source terminals of the differential pair of PMOS transistors are connected to a first common connection node,
two terminal nodes including a ZQnodeCap terminal node and a RefnodeCap terminal node, wherein the ZQnodeCap terminal node and the RefnodeCap terminal node are respectively connected to gate terminals of the differential pair of PMOS transistors, and
load devices including a pair of NMOS transistors arrange in parallel, each of the pair of NMOS transistors being connected in series with corresponding PMOS transistor of the differential pair of PMOS transistors, wherein a drain terminal of each of the pair of NMOS transistors is connected to a drain terminal of the corresponding PMOS transistor of the differential pair of PMOS transistors, the gate terminals of the pair of NMOS transistors are connected to a second common connection node, and the source terminals of the pair of NMOS transistors are respectively connected to a VSS ground.

3. The electrical device of claim 2, wherein the peripheral circuit is configured to provide a constant voltage at the ZQnodeCap terminal node and a RefnodeCap terminal node of the differential amplifier.

4. The electrical device of claim 3, wherein the constant voltage ranges from 100 mV to 250 mV.

5. The electrical device of claim 1, wherein an input voltage variance at the ZQnode terminal node of the peripheral circuit can be transferred to the ZQnodeCap terminal node of the differential amplifier.

6. The electrical device of claim 2, further comprising a DiffRef voltage generator, wherein the DiffRef voltage generator includes a plurality of resistors that are connected in series, one terminal of the plurality of resistors is connected to the VDD source, another terminal of the plurality of resistors is connected to the VSS ground, and the DiffRef voltage generator outputs a DiffRef voltage to the DiffRef node of the peripheral circuit by partitioning voltage applied on the plurality of resistors.

7. The electrical device of claim 2, wherein the first, second, and third precharging transistors of the peripheral circuit are configured to be on or off by adjusting the EQ signal to high or low, respectively, and wherein the fourth PassZQ transistor of the peripheral circuit is configured to be on or off by adjusting the EQ signal to low or high, respectively.

8. The electrical device of claim 7, wherein the ZQnodeCap terminal node, the RefnodeCap terminal node, and the ZQnodeInt node are floating when the first, the second, and the third precharging transistors are turned off, respectively.

9. The electrical device of claim 2, wherein the fourth precharging transistor of the peripheral circuit is configured to be on or off by adjusting the EQ signal to low or high, respectively.

10. The electrical device of claim 5, wherein a voltage level of the RefnodeCap terminal node of the differential amplifier is configured to be constant when the input voltage variance at the ZQnode terminal node of the peripheral circuit is transferred to the ZQnodeCap terminal node of the differential amplifier.

11. An electrical device, comprising:
a first stage of paired differential amplifiers that are arranged in parallel with respect to a peripheral circuit, each of the paired differential amplifiers having a ZQnodeCap terminal node and a RefnodeCap terminal node, and the peripheral circuit being coupled to the ZQnodeCap terminal nodes and a RefnodeCap terminal nodes of the first stage of paired differential amplifiers; and
the peripheral circuit, including:
a ZQnode terminal node and a Refnode terminal node configured to receive input signals to the electrical device,
a CapZQ capacitor having a first terminal connected to the ZQnodeCap terminal node,
a CapRef capacitor having a third terminal connected to the RefnodeCap terminal node and a fourth terminal connected to the Refnode terminal node of the peripheral circuit,
a first precharging transistor having a first source terminal connected to the ZQnodeCap terminal node,
a second precharging transistor having a second source terminal connected to the RefnodeCap terminal node; wherein a first drain terminal of the first precharging transistor and a second drain terminal of the second precharging transistor are connected to a DiffRef node, and the first and second precharging transistors are arranged in parallel with respect to the differential amplifier,
a third precharging transistor having a third source connected to a second terminal of the CapZQ capacitor at a ZQnodeInt node, wherein gate of the first, second, and third precharging transistors are connected in series on an EQ signal line, and
a fourth PassZQ transistor having a fourth source terminal connected to the ZQnodeInt node, a fourth drain terminal connected to the ZQnode terminal node, and a fourth gate terminal connected to the EQ signal line through an inverter.

12. The electrical device of claim 11, further comprising a second stage of paired differential amplifiers that are arranged in parallel, each of the second stage of paired differential amplifiers is connected to outputs of the first stage of paired differential amplifiers.

13. The electrical device of claim 12, further comprising a third stage of differential amplifier that is connected to outputs of the second stage of paired differential amplifiers.

14. The electrical device of claim 11, further comprising a DiffRef voltage generator, wherein the DiffRef voltage generator includes a plurality of resistors that are connected in series, one terminal of the plurality of resistors is connected to a VDD source, another terminal of the plurality of resistors is connected to a VSS ground, and the DiffRef voltage generator outputs a DiffRef voltage to the DiffRef node of the peripheral circuit by partitioning voltage applied on the plurality of resistors.

15. A method of operating an electrical device, comprising:
applying an input voltage on a ZQnode terminal node and Refnode terminal node of a peripheral circuit of the electrical device;
initializing capacitors of the peripheral circuit coupled to a differential amplifier;
floating a ZQnodeInt node, a ZQnodeCap terminal node and a RefnodeCap node, wherein the peripheral circuit is connected to the differential amplifier at the ZQnodeCap terminal node and the RefnodeCap node;
detecting an input voltage variance at the ZQnode terminal node of the peripheral circuit;
transferring the input voltage variance to the ZQnodeCap terminal node of the differential amplifier; and
comparing, by the differential amplifier, voltages applied on ZQnodeCap terminal node and the RefnodeCap node of the differential amplifier.

16. The method of claim 15, wherein initializing capacitors of the peripheral circuit includes:
setting an EQ signal high, wherein the EQ signal is connected to a first, a second, and a third precharging transistors of the peripheral circuit through an EQ signal line, the first precharging transistor has a first source terminal connected to the ZQnodeCap terminal node, the second precharging transistor has a second source terminal connected to the RefnodeCap terminal node, the third precharging transistor has a third source terminal connected to a ZQnodeInt node, and gate terminals of the first, second, and third precharging transistors are connected in series on an EQ signal line, and
turning on the first, second, and third precharging transistors to transfer a DiffRef voltage from a common node connected to source terminals of the first and second precharging transistors to the ZQnodeCap terminal node and RefnodeCap terminal node, and to transfer a Refnode voltage from the Refnode terminal node to the ZQnodeInt node.

17. The method of claim 16, wherein floating the ZQnodeInt node, the ZQnodeCap terminal node and the RefnodeCap terminal node includes setting the EQ signal low and turning off the first, second, and third precharging transistors.

18. The method of claim 16, wherein transferring the input voltage variance to the ZQnodeCap terminal node of the differential amplifier includes setting the EQ signal low and turning on a fourth PassZQ transistor having a fourth source terminal connected to the ZQnodeInt node, a fourth drain terminal connected to the ZQnode terminal node, and a fourth gate terminal connected to the EQ signal line through an inverter.

19. The method of claim 16, wherein the DiffRef voltage is generated by a DiffRef voltage generator, the DiffRef voltage generator includes a plurality of resistors that are connected in series, one terminal of the plurality of resistors is connected to a VDD source, another terminal of the plurality of resistors is connected to a VSS ground, and the DiffRef voltage generator outputs the DiffRef voltage to the DiffRef node of the peripheral circuit by partitioning voltage applied on the plurality of resistors.

20. The method of claim 15, further comprising transferring comparison outputs of the differential amplifier to one or more other differential amplifiers of the electrical device.
